(19) United States
(12) Patent Application Publication
(10) Pub. No.: US 2026/0136994 A1
(43) Pub. Date: May 14, 2026

(54) ELECTRONIC PACKAGE AND MANUFACTURING METHOD THEREOF

(71) Applicant: SILICONWARE PRECISION INDUSTRIES CO., LTD., Taichung City (TW)

(72) Inventors: Wei-Shen HUNG, Taichung City (TW); Wei-Yang LIN, Taichung City (TW)

(73) Assignee: SILICONWARE PRECISION INDUSTRIES CO., LTD., Taichung City (TW)

(21) Appl. No.: 19/058,890

(22) Filed: Feb. 20, 2025

(30) Foreign Application Priority Data
Nov. 14, 2024 (TW) 113143838

(51) Int. Cl. H01L 23/00; G02B 6/12; H01L 21/56; H01L 23/31; H01L 23/538; H01L 25/11

(52) U.S. Cl. CPC H10W 90/00; H10W 70/611; H10W 70/614; H10W 70/65; H10W 74/014; H10W 74/131; G02B 6/12; H10W 72/387; H10W 74/10; H10W 74/15; H10W 90/724; H10W 90/734

(57) ABSTRACT

An electronic package and a manufacturing method thereof are provided, the electronic package has at least one dam at the edge thereof to prevent packaging material from overflowing to the bottom of the electronic package, so that the packaging material is free from contacting the conductive components on the bottom of the electronic package, thereby avoiding problem of non-wetting of the conductive components when the conductive components are subsequently reflowed.

### BACKGROUND

### 1. Technical Field

The present disclosure relates to a semiconductor packaging technology, and more particularly, to an electronic package capable of improving reliability and a manufacturing method thereof.

### 2. Description of Related Art

To ensure the continuous miniaturization and multi-functionality of electronic products and communication equipment, semiconductor packages must evolve toward miniaturization to facilitate multi-pin connection, high-speed operation, and high functionality. For example, in the advanced packaging process, a common type of packaging is a fan-out wiring with embedded components, etc.

FIG. 1A to FIG. 1D are schematic cross-sectional views of a manufacturing method of a conventional semiconductor package 1.

As shown in FIG. 1A, a semi-finished product panel 8 including a plurality of package modules 1a is provided on a carrier 9, wherein the package module 1a includes: an encapsulation layer 15, at least a semiconductor chip 11, a plurality of conductive pillars 13, a circuit structure 10, a wiring structure 14, and a plurality of solder balls 17.

As shown in FIG. 1B, a singulation process is performed on the semi-finished product panel 8 along a cutting path L shown in FIG. 1A to separate each of the electronic modules 1a.

As shown in FIG. 1C, at least an electronic device 16 is disposed on the circuit structure 10 via a plurality of conductive bumps 160. Then, an underfill 18 is formed between the circuit structure 10 and the electronic device 16 to encapsulate the conductive bumps 160.

As shown in FIG. 1D, the carrier 9 is removed to obtain a semiconductor package 1. Afterwards, the semiconductor package 1 is attached to a circuit board 19 by reflowing the solder balls 17.

However, in the manufacturing method of the conventional semiconductor package 1, when the underfill 18 is formed, the underfill 18 is prone to overflow, causing the underfill 18 often to flow from the edge of the circuit structure 10 along the encapsulation layer 15 to the wiring structure 14 shown in FIG. 1C, such that the underfill 18 contacts the solder balls 17 shown in FIG. 1D or even encapsulates the solder balls 17. Thus, when the solder balls 17 subsequently reflowed, the solder balls 17 are prone to non-wet, causing the semiconductor package 1 not to be firmly bonded to the circuit board 19 and further not to be electrically connected to the circuit board 19 effectively, or even causing the semiconductor package 1 to fall off from the circuit board 19, resulting in problems such as poor product reliability.

Therefore, it urgent to overcome the aforementioned problems of conventional techniques.

### SUMMARY

In view of the aforementioned shortcomings of the prior art, the present disclosure provides an electronic package including: an encapsulation layer having a first surface and a second surface opposite to the first surface, and a dam formed at an edge of the first surface; an electronic component embedded in the encapsulation layer; a circuit structure disposed on the first surface of the encapsulation layer with the dam exposed; a wiring structure disposed on the second surface of the encapsulation layer; a plurality of conductive components disposed on the wiring structure; an electronic device disposed on the circuit structure via a plurality of conductive bumps; and a packaging material formed between the circuit structure and the electronic device and encapsulating the plurality of conductive bumps.

The present disclosure further provides a method of manufacturing an electronic package module, the method including: providing a semi-finished product panel comprising a plurality of electronic modules, wherein each of the electronic modules comprises: an encapsulation layer having a first surface and a second surface opposite to the first surface, an electronic component embedded in the encapsulation layer, a circuit structure formed on the first surface of the encapsulation layer, a wiring structure formed on the second surface of the encapsulation layer, and a plurality of conductive components disposed on the wiring structure; removing material of the circuit structure between any two adjacent ones of the electronic modules to expose the first surface of the encapsulation layer; forming a dam on the first surface of the encapsulation layer exposed between any two adjacent ones of the electronic modules; performing a singulation process on the semi-finished product panel along a cutting path to separate each of the electronic modules, allowing the dam formed at an edge of the first surface of the encapsulation layer; disposing an electronic device on the circuit structure via a plurality of conductive bumps; and forming a packaging material between the circuit structure and the electronic device to encapsulate the plurality of conductive bumps.

In the aforementioned electronic package and method, the dam is positioned correspondingly to the cutting path; alternatively, the dam is free from being positioned correspondingly to the cutting path.

In the aforementioned electronic package and method, the dam has a stepped shape.

In the aforementioned electronic package and method, the dam is a recessed portion.

In the aforementioned electronic package and method, the electronic component is electrically connected to the circuit structure.

In the aforementioned electronic package and method, the electronic module further comprises a plurality of conductive pillars that are embedded in the encapsulation layer and electrically connected to the circuit structure and the wiring structure.

In the aforementioned electronic package and method, the plurality of conductive components are electrically connected to the wiring structure.

In the aforementioned electronic package and method, the electronic device is electrically connected to the circuit structure via the plurality of conductive bumps.

In the aforementioned electronic package and method, the packaging material is underfill.

In the aforementioned electronic package and method, the packaging material extends to the dam rather than to the wiring structure.

As can be seen from the above, the electronic package and the manufacturing method thereof of the present disclosure mainly dispose a dam at the edge of the first surface of the encapsulation layer to constrain the overflow range of the packaging material and to prevent the packaging material from overflowing to the wiring structure, so that the packaging material would not contact the conductive components. Therefore, compared to the prior art, the electronic package of the present disclosure can avoid the problem of non-wetting of the conductive components when the conductive components are subsequently reflowed, thereby improving the reliability of products.

### BRIEF DESCRIPTION OF THE DRAWINGS

FIG. 1A to FIG. 1D are schematic cross-sectional views showing a method of manufacturing a conventional semiconductor package.

FIG. 2A to FIG. 2E are schematic cross-sectional views showing a method of manufacturing an electronic package according to the present disclosure.

FIG. 3 is a schematic cross-sectional view showing another embodiment of FIG. 2E.

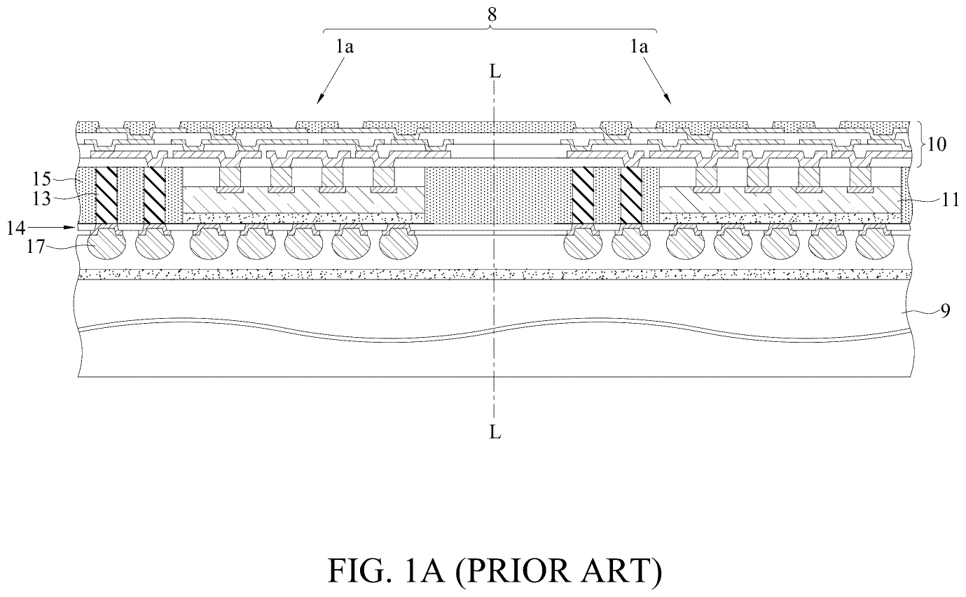

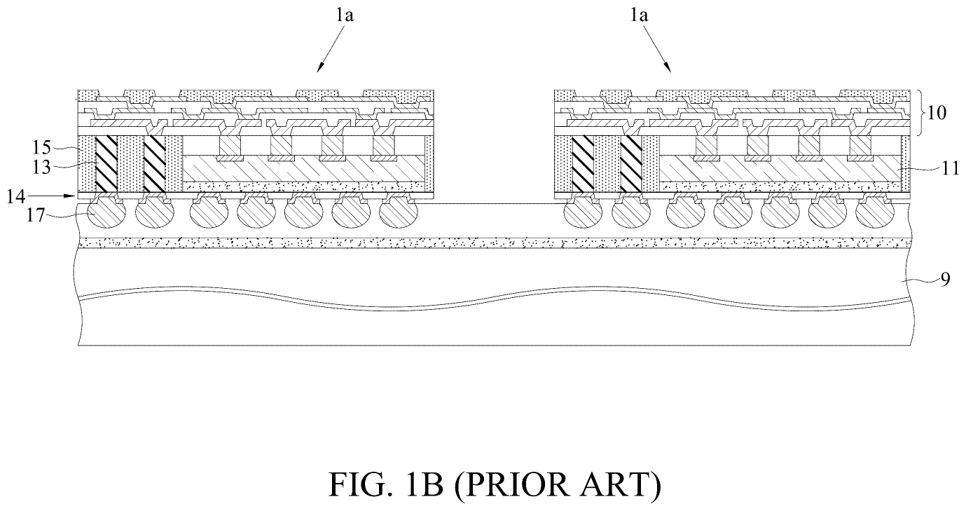

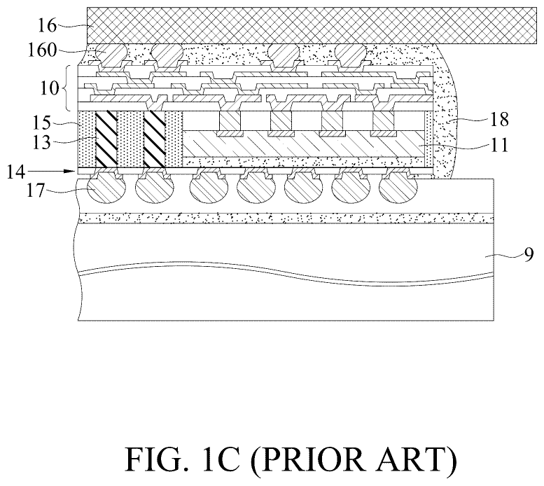

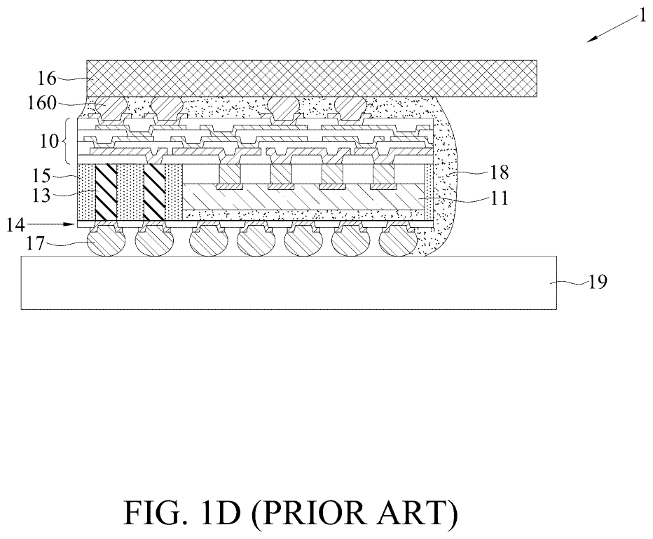

### DETAILED DESCRIPTION

The following describes the implementation of the present disclosure with examples. Those skilled in the art can easily understand other advantages and effects of the present disclosure from the contents disclosed in this specification.

It should be understood that, the structures, ratios, sizes, and the like in the accompanying figures are used for illustrative purposes to facilitate the perusal and comprehension of the contents disclosed in the present specification by one skilled in the art, rather than to limit the conditions for practicing the present disclosure. Any modification of the structures, alteration of the ratio relationships, or adjustment of the sizes without affecting the possible effects and achievable proposes should still be deemed as falling within the scope defined by the technical contents disclosed in the present specification. Meanwhile, terms such as “on,” “first,” “second,” “a,” and the like are merely used for clear explanation rather than limiting the practicable scope of the present disclosure, and thus, alterations or adjustments of the relative relationships thereof without essentially altering the technical contents should still be considered in the practicable scope of the present disclosure.

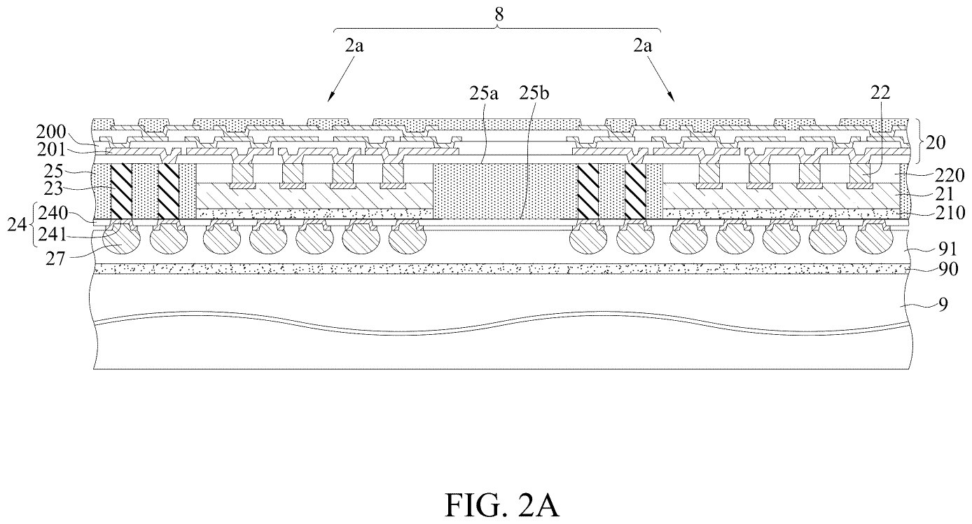

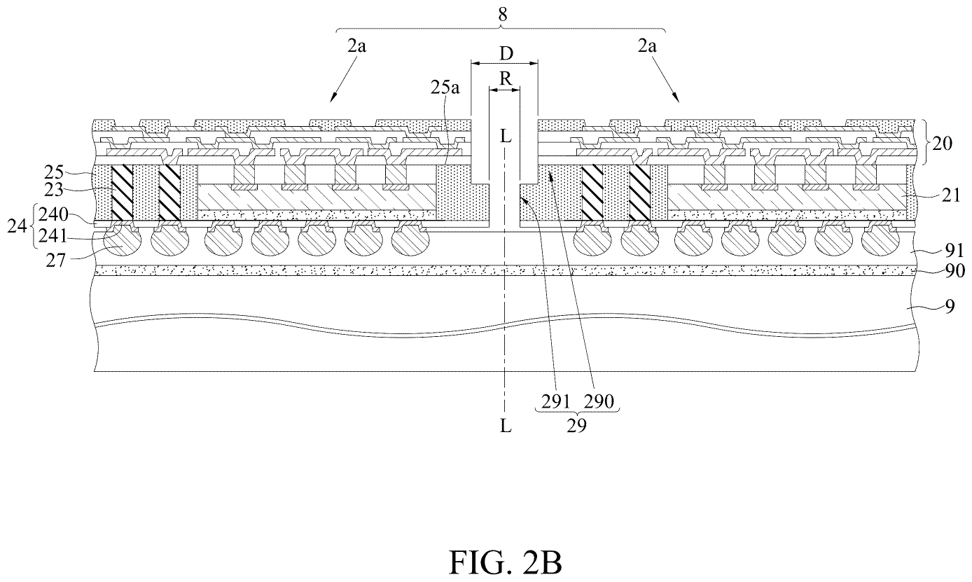

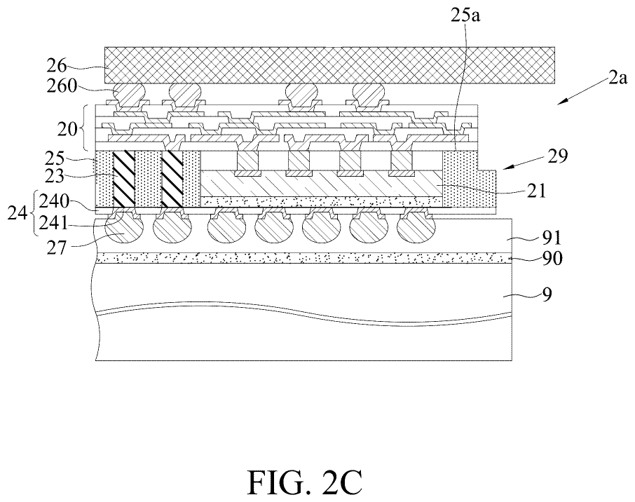

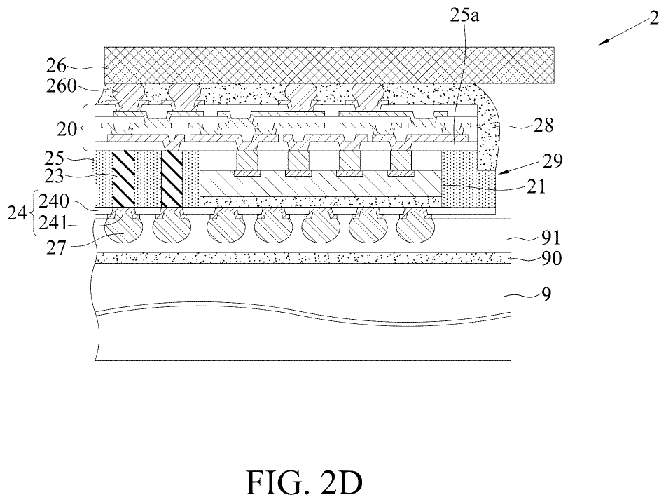

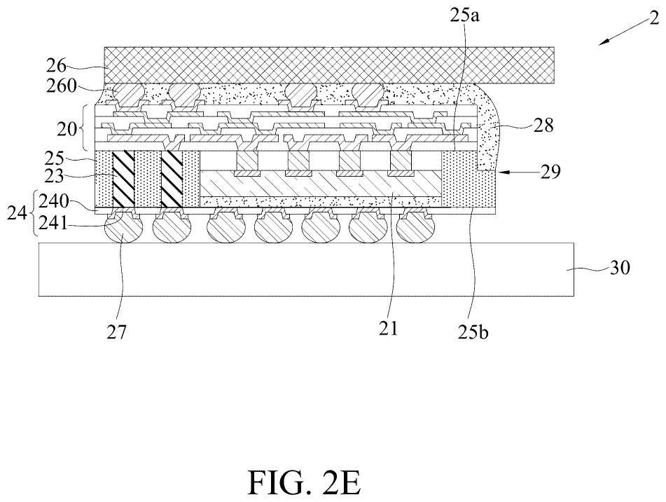

FIG. 2A to FIG. 2E are schematic cross-sectional views showing a method of manufacturing an electronic package 2 of the present disclosure.

As shown in FIG. 2A, a semi-finished product panel 8 including a plurality of electronic modules 2a is provided on a carrier 9. The electronic module 2a includes: an encapsulation layer 25, at least an electronic component 21, a plurality of conducive pillars 23, a circuit structure 20, a wiring structure 24, and a plurality of conductive components 27.

In an embodiment, the carrier 9 is, for example, a board made of semiconductor material (such as silicon or glass), on which a release layer 90 and a bonding layer 91, such as an insulating material, are sequentially formed by, for example, coating.

The encapsulation layer 25 has a first surface 25a and a second surface 25b opposite to the first surface 25a.

In an embodiment, the encapsulation layer 25 is made of an insulating material, such as polyimide (PI), dry film, epoxy encapsulation compound or epoxy molding compound. For example, the encapsulation layer 25 may be formed by process such as liquid compound, injection, lamination, or compression molding.

The electronic component 21 is embedded in the encapsulation layer 25, and a plurality of conductors 22 are bonded with and electrically connected to the electrode pads of the electronic component 21. The electrode component 21 is an active component, a passive component, or a combination of the active component and the passive component. The active component is, for example, a semiconductor chip, and the passive component is, for example, a resistor, a capacitor, or an inductor.

In an embodiment, the electronic component 21 is a semiconductor chip, which is disposed on the wiring structure 24 via an adhesive layer 210, and the conductors 22 are encapsulated by a protective film 220 such as a passivation material.

In addition, the conductors 22 are, for example, but is not limited to, conductive circuits, spherical conductors such as solder balls, columnar-shaped metal conductors such as copper pillars, solder bumps, etc., or stud-shaped conductors made by a wire bonding machine.

The conductive pillars 23 are embedded in the encapsulation layer 25 and are made of metallic material such as copper or made of solder material.

The circuit structure 20 is disposed on the first surface 25a of the encapsulation layer 25 and electrically connected to the conductive pillars 23 and the conductors 22.

In an embodiment, the circuit structure 20 includes a plurality of dielectric layers 200 and a circuit layer 201 formed on the dielectric layer 200, and the circuit structure 20 is of, for example, a redistribution layer (RDL) specification. The outermost dielectric layer 200 may serve as a solder-resist layer, and the outermost circuit layer 201 is exposed from the solder-resist layer to serve as electrical contact pads. Alternatively, the circuit structure 20 may include only a single dielectric layer 200 and a single circuit layer 201.

In addition, the circuit layer 201 is made of copper. The dielectric layer 200 is made of dielectric material such as polybenzoxazole (PBO), polyimide (PI), or prepreg (PP), or made of solder-resist material such as green paint, ink, etc.

The wiring structure 24 is disposed on the second surface 25b of the encapsulation layer 25 and electrically connected to the conductive pillars 23.

In an embodiment, the wiring structure 24 includes an insulating layer 240 and a wiring layer 241 formed on the insulating layer 240, and the wiring structure 24 is of, for example, a redistribution layer (RDL) specification The outermost insulating layer 240 may serve as a solder-resist layer, and the outermost wiring layer 241 is exposed from the solder-resist layer to serve as electrical contact pads.

Furthermore, the wiring layer 241 is made of copper The insulating layer 240 is made of dielectric material such as polybenzoxazole (PBO), polyimide (PI), or prepreg (PP), or made of solder-resist material such as green paint, ink, etc.

The conductive components 27 are solder balls or a metal bumps, such as copper bumps, and are disposed on the electrical contact pads of the wiring structure 24 and electrically connected to the wiring layer 241.

In an embodiment, the semi-finished product panel 8 is disposed on the carrier 9 with one side of its wiring structure 24, so that the conductive components 27 are embedded in the bonding layer 91.

As shown in FIG. 2B, the material of the circuit layer 20 between each of the electronic modules 2a is removed to expose the first surface 25a of the encapsulation layer 25, and part of the material of the exposed first surface 25a of the encapsulation layer 25 is removed together, so as to form a recessed portion 290 communicating the circuit structure 20 and the encapsulation layer 25 on the first surface 25a of the encapsulation layer 25. Then, a hollow portion 291 is formed at the bottom of the recessed portion 290 to penetrate the encapsulation layer 25 and the wiring structure 24. Further, a dam 29 has a stepped shape and is formed on the first surface 25a of the encapsulation layer 25 at the edge of each of the electronic modules 2a.

In an embodiment, the width D of the recessed portion 290 is greater than the width R of the hollow portion 291. For example, a tool with a wider cutting end is used to form the recessed portion 290, and then a tool with a narrower cutting end is used to form the hollow portion 291.

As shown in FIG. 2C, a singulation process is performed on the semi-finished product panel 8 along the cutting path L as shown in FIG. 2B to separate each of the electronic modules 2a, so the dam 29 is formed at the edge of the first surface 25a of the encapsulation layer 25. And then, at least one electronic device 26 is disposed on the circuit structure 20 via a plurality of conductive bumps 260.

In an embodiment, the cutting path L corresponds to the position of the hollow portion 291, so that the dam 29 has a stepped shape.

The electronic device 26 is electrically connected to the electrical contact pads of the circuit layer 201 via the plurality of conductive bumps 260 such as solder bumps, copper bumps, or others. For example, the electronic device 26 is an optical communication component, such as a photonic IC (PIC).

As shown in FIG. 2D, a packaging material 28 such as underfill is formed between the circuit structure 20 and the electronic device 26 to encapsulate the conductive bumps 260 to further obtain the electronic packages 2.

In an embodiment, the packaging material 28 extends to the dam 29 rather than the wiring structure 24.

As shown in FIG. 2E, the carrier 9, and the release layer 90 and the bonding layer 91 thereon are removed to expose the conductive components 27. Afterwards, the electronic package 2 is placed on a carrying structure 30 by reflowing the conductive components 27.

In an embodiment, the carrying structure 30 is in the form of a substrate, such as a package substrate with core layer or a coreless packaging substrate. Alternatively, the carrying structure 30 may also be other board, such as a lead frame, wafer, or other carrying board with metal routings, etc., and not limited to the above.

Therefore, the manufacturing method of the present disclosure mainly disposes a dam 29 at the edge of the first surface 25a of the encapsulation layer 25 to constrain the overflow range of the packaging material 28 by its surface tension and to prevent the packaging material 28 from overflowing to the wiring structure 24, so that the packaging material 28 would not contact the conductive components 27. Thus, compared to the prior art, the electronic package 2 of the present disclosure can avoid the problem of non-wetting of the conductive components 27 when the conductive components 27 are subsequently reflowed, so that the electronic package 2 can be firmly bonded to the carrying structure 30 and electrically connected to the carrying structure 30 effectively, thereby improving the reliability of products.

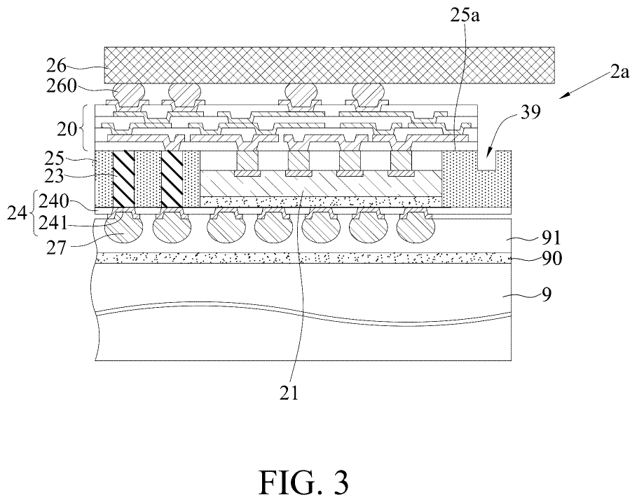

Referring to FIG. 3, in another embodiment, the material of the circuit structure 20 between each of the electronic modules 2a can be removed by using a tool with a wider cutting end, so as to expose the first surface 25a of the encapsulation layer 25, and then a recessed portion without penetrating the encapsulation layer 25 is formed on the exposed first surface 25a of the encapsulation layer 25 by using a tool with a narrower cutting end to serve as the dam 39, and the position of the dam 39 does not correspond to the cutting path L, so that the dam 39 is formed in the form of a recessed portion at the edge of the first surface 25a of the encapsulation layer 25. Therefore, there are various structural types of the dam and there are no special limitations.

The present disclosure further provides an electronic package 2, the electronic package 2 includes: an encapsulation layer 25, at least an electronic component 21 embedded in the encapsulation layer 25, a plurality of conductive pillars 23 embedded in the encapsulation layer 25, a circuit structure 20, a wiring structure 24, a plurality of conductive components 27 disposed on the wiring structure 24, an electronic device 26, and a packaging material 28.

The encapsulation layer 25 has a first surface 25a and a second surface 25b opposite to the first surface 25a, and a dam 29, 39 is formed at the edge of the first surface 25a.

The circuit structure 20 is disposed on the first surface 25a of the encapsulation layer 25 and the dam 29, 39 is exposed.

The wiring structure 24 is disposed on the second surface 25b of the encapsulation layer 25.

The electronic device 26 is disposed on the circuit structure 20 via a plurality of conductive bumps 260.

The packaging material 28 is formed between the circuit structure 20 and the electronic device 26 to encapsulate the plurality of conductive bumps 260.

In an embodiment, the dam 29 has a stepped shape.

In an embodiment, the dam 39 is a recessed portion.

In an embodiment, the electronic component 21 is electrically connected to the circuit structure 20.

In an embodiment, the conductive pillars 23 are electrically connected to the circuit structure 20 and the wiring structure 24.

In an embodiment, the plurality of conductive components 27 are electrically connected to the wiring structure 24.

In an embodiment, the electronic device 26 is electrically connected to the circuit structure 20 via the plurality of conductive bumps 260.

In an embodiment, the packaging material 28 is underfill.

In an embodiment, the packaging material 28 extends to the dam 29, 39 rather than to the wiring structure 24.

To sum up, the electronic package and the manufacturing method thereof of the present disclosure prevent the packaging material from overflowing onto the wiring structure via the dam, so as to prevent the packaging material from overflowing to the wiring structure, thus the packaging material would not contact the conductive component. Therefore, compared to the prior art, the electronic package of the present disclosure can avoid the problem of non-wetting of the conductive components when the conductive components are subsequently reflowed, thereby improving the reliability of products.

The above embodiments are disposed for illustrating the principles of the present disclosure and its technical effect, and should not be construed as to limit the present disclosure in any way. The above embodiments can be modified by one of ordinary skill in the art without departing from the spirit and scope of the present disclosure. Therefore, the scope claimed of the present disclosure should be defined by the following claims.

What is claimed is:

1. An electronic package, comprising:
an encapsulation layer having a first surface and a second surface opposite to the first surface, and a dam formed at an edge of the first surface;
an electronic component embedded in the encapsulation layer;
a circuit structure disposed on the first surface of the encapsulation layer with the dam exposed;
a wiring structure disposed on the second surface of the encapsulation layer;
a plurality of conductive components disposed on the wiring structure;
an electronic device disposed on the circuit structure via a plurality of conductive bumps; and
a packaging material formed between the circuit structure and the electronic device and encapsulating the plurality of conductive bumps.

2. The electronic package of claim 1, wherein the dam has a stepped shape.

3. The electronic package of claim 1, wherein the dam is a recessed portion.

4. The electronic package of claim 1, wherein the electronic component is electrically connected to the circuit structure.

5. The electronic package of claim 1, further comprising a plurality of conductive pillars that are embedded in the encapsulation layer and electrically connected to the circuit structure and the wiring structure.

6. The electronic package of claim 1, wherein the plurality of conductive components are electrically connected to the wiring structure.

7. The electronic package of claim 1, wherein the electronic device is electrically connected to the circuit structure via the plurality of conductive bumps.

8. The electronic package of claim 1, wherein the packaging material is underfill.

9. The electronic package of claim 1, wherein the packaging material extends to the dam rather than to the wiring structure.

10. A method of manufacturing an electronic package module, comprising:
providing a semi-finished product panel comprising a plurality of electronic modules, wherein each of the electronic modules comprises: an encapsulation layer having a first surface and a second surface opposite to the first surface, an electronic component embedded in the encapsulation layer, a circuit structure formed on the first surface of the encapsulation layer, a wiring structure formed on the second surface of the encapsulation layer, and a plurality of conductive components disposed on the wiring structure;
removing material of the circuit structure between any two adjacent ones of the electronic modules to expose the first surface of the encapsulation layer;
forming a dam on the first surface of the encapsulation layer exposed between any two adjacent ones of the electronic modules;
performing a singulation process on the semi-finished product panel along a cutting path to separate each of the electronic modules, allowing the dam formed at an edge of the first surface of the encapsulation layer;
disposing an electronic device on the circuit structure via a plurality of conductive bumps; and
forming a packaging material between the circuit structure and the electronic device to encapsulate the plurality of conductive bumps.

11. The method of claim 10, wherein the dam has a stepped shape.

12. The method of claim 10, wherein the dam is positioned correspondingly to the cutting path.

13. The method of claim 10, wherein the dam is a recessed portion.

14. The method of claim 10, wherein the dam is free from being positioned correspondingly to the cutting path.

15. The method of claim 10, wherein the electronic component is electrically connected to the circuit structure.

16. The method of claim 10, wherein the electronic module further comprises a plurality of conductive pillars that are embedded in the encapsulation layer and electrically connected to the circuit structure and the wiring structure.

17. The method of claim 10, wherein the plurality of conductive components are electrically connected to the wiring structure.

18. The method of claim 10, wherein the electronic device is electrically connected to the circuit structure via the plurality of conductive bumps.

19. The method of claim 10, wherein the packaging material is underfill.

20. The method of claim 10, wherein the packaging material extends to the dam rather than to the wiring structure.
